(19) United States
(12) Patent Application Publication
(10) Pub. No.: US 2011/0193224 A1
(43) Pub. Date: Aug. 11, 2011

(54) SEMICONDUCTOR DEVICE

(75) Inventors: Hiroyasu Ito, Nagoya-city (JP); Kazuhiro Kubo, Chitose-city (JP)

(73) Assignees: DENSO CORPORATION, Kariya-city (JP); MITSUMI ELECTRIC CO., LTD., Tokyo (JP)

(21) Appl. No.: 13/020,126

(22) Filed: Feb. 3, 2011

(30) Foreign Application Priority Data
Feb. 10, 2010 (JP) 2010-27588

(51) Int. Cl. H01L 23/488

(52) U.S. Cl. 257/737; 257/E23.023

(57) ABSTRACT

In a semiconductor device, a pad electrode is disposed on a surface of a semiconductor substrate, and a surface-protective film is disposed on the surface of the semiconductor substrate and the pad electrode. The surface-protective film has an opening to expose a part of the pad electrode. A bump electrode is disposed on the part of the pad electrode exposed from the opening, and a bump is disposed on the bump electrode. The surface-protective film further has a slit at a location above the pad electrode. The slit has a frame shape surrounding a periphery of the bump electrode. The slit extends from a surface of the surface-protective film, which is opposite to the semiconductor substrate, and reaches the pad electrode.

### CROSS REFERENCE TO RELATED APPLICATION

This application is based on Japanese Patent Application No. 2010-27588 filed on Feb. 10, 2010, the disclosure of which is incorporated herein by reference.

### FIELD OF THE INVENTION

The present invention relates to a semiconductor device in which a bump is disposed on a pad electrode through a bump electrode on a semiconductor substrate.

### BACKGROUND OF THE INVENTION

In a semiconductor device, for example, an aluminum (Al) pad is disposed on a semiconductor substrate such as a silicon substrate in which semiconductor, element is formed, and a surface-protective film is overlaid on the Al pad. The surface-protective film has an opening to expose a part of the Al pad. A bump is disposed on the exposed part of the Al pad through a bump electrode.

When such a semiconductor device is mounted on a board such as a ceramic board by reflow soldering, the surface-protective film receives a thermal stress due to a difference in coefficient of thermal expansion between elements such as the silicon substrate the bump electrode, the ceramic board and the surface-protective film. As a result, cracks are formed in the surface-protective film from a contact portion with the bump electrode.

Therefore, structures for reducing the cracks in such a semiconductor device have been proposed. For example, in a semiconductor device described in Japanese Patent Application Publication No. 2006-269971, slits are formed in a surface-protective film in a discontinuous manner around an Al pad. When the semiconductor device is mounted on a board such as a ceramic board by reflow soldering, the thermal stress to the surface-protective film due to the difference of coefficient of thermal expansion may be alleviated by the slits. Therefore, the occurrence of cracks in the surface-protective film from a contact portion with a bump electrode may be reduced.

In a semiconductor device described in Japanese Patent Application Publication 11-330121, slits are formed in an Al pad. The thermal stress may be alleviated by the slits of the Al pad, and hence the occurrence of cracks in a surface-protective film from a contact portion with a bump electrode may be reduced.

Further, Japanese Patent Application Publication No. 4-125932 describes to employ a polyimide base resin film between a bump electrode and a surface-protective film so as to alleviate the thermal stress.

In the semiconductor devices of Publications No. 2006-269971 and No. 11-330121, although, the thermal stress may be alleviated by the slits, it is difficult to sufficiently alleviate the thermal stress. Therefore, during the reflow soldering, cracks will be formed in the surface-protective film from the contact portion with the bump electrode. In the semiconductor device of Publication No. 4-125932, although the thermal stress may be alleviated by the polyimide base resin film, it is difficult to sufficiently alleviate the thermal stress. Therefore, cracks will be formed in the surface-protective film from the contact portion with the bump electrode.

If the cracks extend beyond the Al pad, water or the like will enter the inside of the semiconductor device through the cracks. As a result, reliability of the semiconductor device is degraded.

In addition, the thermal stress is likely to be generated also during the use of the semiconductor device, such as a continuous use in a high temperature environment and a low temperature environment. Also in such a use condition, the above drawbacks are likely to be made.

Further, in the semiconductor device of Publication No. 2006-269971, since the slits are formed in the surface-protective film in the discontinuous manner around the Al pad, water or the like may enter the inside of the semiconductor device through the slits.

### SUMMARY OF THE INVENTION

The present invention is made in view of the above matter, and it is an object of the present invention to provide a semiconductor device capable of reducing reliability degradation.

In a semiconductor device according to an aspect, a pad electrode is disposed on a surface of a semiconductor substrate, and a surface-protective film is disposed on the surface of the semiconductor substrate and the pad electrode. The surface-protective film has an opening and a part of the pad electrode is exposed from the opening. A bump electrode is disposed on the part of the pad electrode exposed from the opening, and a bump is disposed on the bump electrode. The surface-protective film further has a slit at a location above the pad electrode. The slit has a frame shape surrounding a periphery of the bump electrode. The slit passes through the surface-protective film from a surface opposite to the semiconductor substrate and reaches the pad electrode.

When the semiconductor device is mounted on a board such as a ceramic board by reflow soldering or when the semiconductor device is continuously used in a high temperature environment and a low temperature environment, a thermal stress can be alleviated by the slit. Therefore, an occurrence of cracks due to the thermal stress is reduced. Further, even if a crack is generated in the surface-protective film from a contact portion with the bump electrode, an extension of the crack is terminated at the slit. Therefore, it is less likely that the crack will extend in the surface-protective film beyond the pad electrode. In other words, even if such a crack is formed, the crack remains only in a portion of the surface-protective film located on the pad electrode. Therefore, even if water or the like enter the crack, the entry of the water or the like is restricted by the pad electrode. As such, it is less likely that the water or the like will enter the inside of the semiconductor device. Accordingly, reliability of the semiconductor device is not degraded.

For example, the frame shape of the slit is a continuous and closed loop shape, such as a continuous circular shape.

### BRIEF DESCRIPTION OF THE DRAWINGS

Other objects, features and advantages of the present invention will become more apparent from the following detailed description made with reference to the accompanying drawings, in which like parts are designated by like reference numbers and in which:

FIG. 1A is a schematic cross-sectional view of a semiconductor device according to a first embodiment of the present invention;

FIG. 1B is a plan view of the semiconductor device shown in FIG. 1A;

FIG. 2 is a graph showing a relationship between a crack length and a crack ratio of the semiconductor device shown in FIGS. 1A and 1B and semiconductor device of a comparative example;

FIG. 3 is a graph showing a crack occurrence ratio of the semiconductor device shown in FIGS. 1A and 1B and the semiconductor device of the comparative example; and

FIG. 4 is a schematic cross-sectional view of a semiconductor device according to a second embodiment of the present invention.

### DETAILED DESCRIPTION OF EXEMPLARY EMBODIMENTS

### First Embodiment

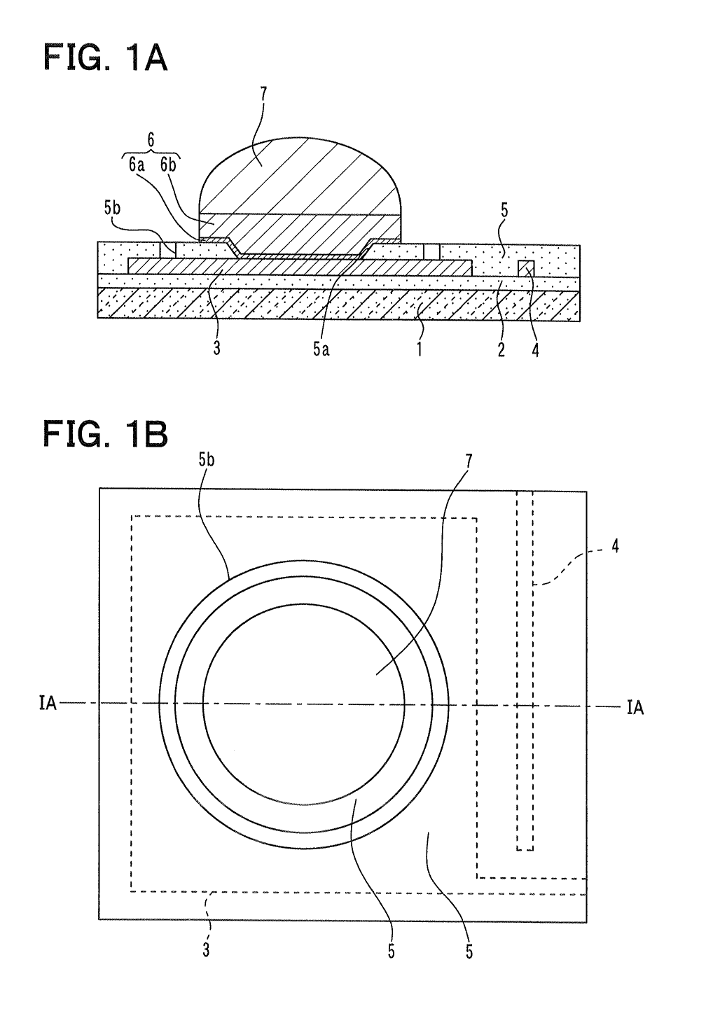

A first embodiment of the present invention will be described with reference to FIGS. 1A and 1B. FIG. 1A is a schematic cross-sectional view of a semiconductor device according to the present embodiment. FIG. 1B is a plan view such as a top view of the semiconductor device shown in FIG. 1A. Also, FIG. 1A corresponds to a cross-section taken along a line IA-IA in FIG. 1B.

As shown in FIG. 1A, the semiconductor device includes a semiconductor substrate such as a silicon substrate 1, an interlayer insulating film 2, a pad electrode and a wiring (circuit) 4. The interlayer insulating film 2 is disposed along a surface of the semiconductor substrate 1 in which semiconductor elements (not shown) are formed. The interlayer insulating film 2 is, for example, constructed of a silicon oxide film. The pad electrode 3 and the wiring 4 are disposed on the interlayer insulating film 2. The pad electrode 3 is, for example, made of aluminum (Al). The pad electrode 3 has a generally square shape, for example. However, the pad electrode 3 may have any other shape.

The semiconductor device further includes a surface-protective film 5, bump electrode 6 and a solder bump 7. The surface-protective film 5 is, for example, constructed of a silicon nitride film. The surface-protective film 5 is disposed to cover the pad electrode 3 and the wiring 4 on the surface of the silicon substrate 1. Further, the surface-protective film 5 is formed with an opening 5a to expose at least a part of the pad electrode 3.

The bump electrode 6 is disposed on the surface of the pad electrode 3, which is exposed from the opening 5a. In the present embodiment, the bump electrode 6 is disposed on a wall defining the opening 5a and on a perimeter portion of the opening 5a, in addition to the exposed surface of the pad electrode 3.

For example, the bump electrode 6 has a diameter larger than a diameter of the opening 5a. Thus, the bump electrode 6 exists on the exposed surface of the pad electrode 3, the wall of the surface-protective film 5 defining the opening 5a and a peripheral portion of the opening 5a.

For example the bump electrode 6 includes a barrier metal film 6a and a metal electrode portion 6b. The barrier metal film 6a is, for example, constructed of a titanium alloy film. The metal electrode portion 6b is layered on the barrier metal film 6a. The metal electrode portion 6b is made of a material having sufficient wettability with a solder. For example, the metal electrode portion 6b is made of copper (Cu).

The solder bump 7 is disposed on the bump electrode 6. The solder bump 7 is, for example, made of a lead- (Pb-) free solder, such as Sn—Ag base solder. Further, the solder bump 7 can be made of a Pb—Sn base eutectic solder.

The surface-protective film 5 has a slit 5b at a location above the pad electrode 3. The slit 5b has a frame shape surrounding a periphery of the bump electrode 6. The slit 5b passes through the surface-protective film 5 above the pad electrode 3. That is, the slit 5b extends from a surface of the surface-protective film 5, which is opposite to the silicon substrate 1, and reaches the pad electrode 3. Thus, in the surface-protective film 5, an inner portion located inside of the slit 5b is separated from an outer portion located outside of the slit 5b by the slit 5b.

In the present embodiment, the slit 5b has a circular shape, as shown in FIG. 1B. For example, the frame shape of the slit 5b is a continuous and closed loop shape, such as a continuous circular shape.

As described above, in the semiconductor device according to the present embodiment, the surface-protective film 5 has the slit 5b at the location above the pad electrode 3. The slit 5b has the frame shape surrounding the periphery of the bump electrode 6. Therefore, when the semiconductor device is mounted on a board such as a ceramic board by reflow soldering and/or is continuously used in a high temperature environment and a low temperature environment, even if a crack is formed in the surface-protective film 5 from a portion contacting the bump electrode 6, the slit 5b restricts an extension of the crack.

As such, it is less likely that the crack will extend beyond the pad electrode 3. That is, the crack exists only within the portion of the surface-protective film 5, which is located on the pad electrode 3. For example, the crack can be limited within the inner portion of the surface-protective film 5.

Therefore, even if water or the like enters the crack, the entry of the water or the like is restricted by the pad electrode 3. Accordingly, it is less likely that the water or the like will enter the inside of the semiconductor device, and hence reliability of the semiconductor device is not degraded.

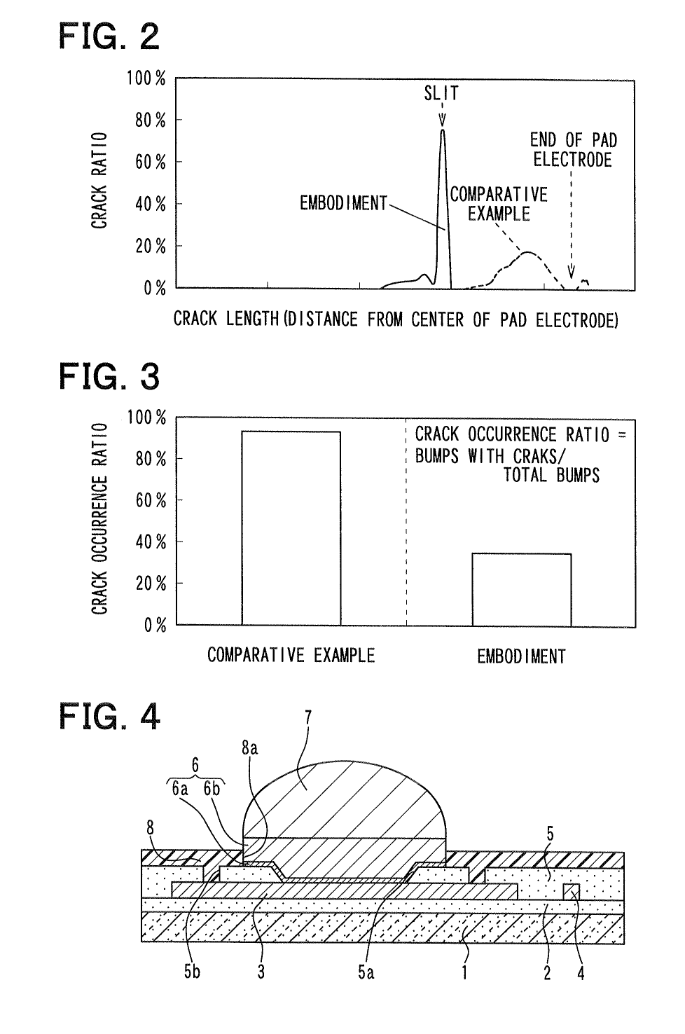

FIG. 2 shows a relationship between a crack length and a crack ratio of each the semiconductor device according to the present embodiment and semiconductor device of a comparative example, when mounted on the board. The crack length is defined by a distance from the center of the pad electrode 3. The crack ratio is a ratio of the number of cracks equidistant from the center of the pad electrode 3 to the number of cracks formed (i.e., the number of cracks with the equal length/the total number of cracks).

In FIG. 2, a solid line represents the crack ratio of the semiconductor device according to the present embodiment, and a dashed line represents the crack ratio of the semiconductor device of the comparative example. The semiconductor device of the comparative example does not have a slit in the surface-protective film.

According to FIG. 2, in the semiconductor device of the comparative example, the cracks extend beyond the pad electrode 3. In the semiconductor device according to the present embodiment, on the other hand, the cracks do not extend beyond the slit 5b. That is, it is confirmed that the extension of the cracks can be terminated by the slit 5b.

In the present embodiment, the thermal stress caused when the semiconductor device is mounted on the board or continuously used in the high temperature condition and the low temperature condition can be alleviated by the frame-shaped slit 5b, as compared with the semiconductor device of the comparative example. As such, an occurrence of the cracks can also be reduced.

FIG. 3 shows a crack occurrence ratio of each of the semiconductor device according to the present embodiment and the semiconductor device of the comparative example, when mounted on the board. The crack occurrence ratio is a ratio of the number of bumps in which a crack(s) is formed to the total number of bumps (i.e the number of bumps with the crack(s)/the total number of bumps).

According to FIG. 3, it is confirmed that the occurrence of the cracks can be reduced in the semiconductor device according to the present embodiment, as compared with the semiconductor device of the comparative example.

Accordingly, in the present embodiment, the extension of the cracks can be restricted as well as the occurrence of the cracks can be reduced.

As described above, in the semiconductor device according to the present embodiment, even if the crack is generated in the surface-protective film 5, the extension of the crack can be terminated at the slit 5b. Therefore, the solder bump 7 can be made of not only the Pb—Sn base eutectic solder, but also the Sn—Ag base solder, which is harder and has a higher melting point than the Pb—Sn base eutectic solder.

That is, when the Sn—Ag base solder is employed as the solder bump 7, since the melting point of the Sn—Ag base solder is higher than that of the Pb—Sn base eutectic solder, the temperature of the reflow soldering is high, as compared with the case using the Pb—Sn base eutectic solder. Thus, the thermal stress due to the difference in coefficient of thermal expansion between elements such as the silicon substrate 1, the surface-protective film 5, the bump electrode 6 and the board is large. Further, since the Sn—Ag base solder is harder than the Pb—Sn base eutectic solder, the thermal stress alleviated by the solder bump 7 is small. That is, when the Sn—Ag base solder is employed, the crack is, more easily formed and is more easily extended, as compared with the case employing the Pb—Sn base eutectic solder.

In the present embodiment, since the extension of the crack can be terminated by the slit 5b, the Sn—Ag base solder or the similar solder, which is harder than the Pb—Sn base solder and has the melting point higher than that of the Pb—Sn base solder, can be employed. Thus, the structure can meet a recent demand for a use of a Pb-free solder.

Further, in the semiconductor device according to the present embodiment, since the slit 5b is located on the pad electrode 3, it is less likely that water or the like will enter the inside of the semiconductor device through the slit 5b.

Moreover, since the thermal stress is alleviated by the slit 5b as well as the thermal stress is released by the crack generated in the inner portion of the surface-protective film 5, it is less likely that a crack will be generated in the interlayer insulating film 2.

### Second Embodiment

A second embodiment of the present invention will be described. A semiconductor device according to the present embodiment additionally has a resin film on the surface-protective film 5 in the structure of the first embodiment. Other structures are similar to those of the first embodiment, and a different structure will be mainly described hereinafter. FIG. 4 is a schematic cross-sectional view of the semiconductor device according to the present embodiment.

As shown in FIG. 4, the semiconductor device according to the present embodiment has a resin film 8 covering the surface-protective film 5. The resin film 8 is formed with an opening 8a to expose the bump electrode 6, for example, to expose the metal electrode portion 6b. The resin film 8 is made of a resin having a heat resistance, such as a polyimide base resin.

The resin film 8 covers the surface-protective film 5. The resin film 8 can alleviate the thermal stress generated when the semiconductor device is mounted on the board. Also, the resin film 8 can alleviate the thermal stress generated when the semiconductor device is continuously used in the high temperature condition and the low temperature condition. Accordingly, the crack in the surface-protective film 5 can be further restricted, and the advantages similar to the first embodiment can be achieved.

### Other Embodiments

In the first and second embodiment, the slit 5b exemplarily has the circular shape. Alternatively the slit 5b may have a rectangular shape or a polygonal shape.

In the first and second embodiments, the bump electrode 6 is exemplarily formed on the wall forming the opening 5b and on the perimeter portion of the opening 5b, in addition to the location above the exposed surface of the pad electrode 3 exposed from the opening 5a. As another example, the bump electrode 6 may be formed only above the exposed surface of the pad electrode 3 and on the wall forming the opening 5a. As further another example the bump electrode 6 may be formed only above the exposed surface of the pad electrode 3.

In the first and second embodiments, the bump electrode 6 exemplarily has the barrier metal film 6a and the metal electrode portion 6b layered on the barrier metal film 6a. As another example, the bump electrode 6 may have only the barrier metal film 6a. Further, the barrier metal film 6a may be made of any other material.

Additional advantages and modifications will readily occur to those skilled in the art. The invention in its broader term is therefore not limited to the specific details, representative apparatus, and illustrative examples shown and described.

What is claimed is:

1. A semiconductor device comprising:
a semiconductor substrate;
a pad electrode disposed on a surface of the semiconductor substrate;
a surface-protective film disposed on the surface of the semiconductor substrate and the pad electrode, the surface-protective film having an opening to expose a part of the pad electrode;
a bump electrode disposed above the part of the pad electrode exposed from the opening; and
a bump disposed on the bump electrode,
wherein the surface-protective film further has a slit at a location above the pad electrode, the slit has a frame shape surrounding a periphery of the bump electrode, and the slit passes through the surface-protective film from a surface opposite to the semiconductor substrate and reaches the pad electrode.

2. The semiconductor device according to claim 1, further comprising:
a resin film disposed on the surface-protective film, wherein the resin film has an opening and the bump electrode is exposed through the opening of the resin film.

3. The semiconductor device according to claim 2, wherein the resin film is made of a polyimide base resin.

4. The semiconductor device according to claim 1, wherein the bump electrode includes a barrier metal film disposed on the part of the pad electrode exposed from the opening of the surface-protective film and a metal electrode portion layered on the barrier metal film.

5. The semiconductor device according to claim 1, wherein the frame shape of the slit is a continuous and closed loop shape.

6. The semiconductor device according to claim wherein the frame shape slit is a continuous circular shape.
